(19) United States
(12) Patent Application Publication
(10) Pub. No.: US 2019/0287821 A1
(43) Pub. Date: Sep. 19, 2019

(54) APPARATUS AND METHOD FOR INCREASED PURGE VELOCITY IN SPECIALTY GAS SYSTEMS

(71) Applicant: GLOBALFOUNDRIES Inc., Grand Cayman (KY)

(72) Inventor: Craig DEVARNEY, Essex Junction, VT (US)

(21) Appl. No.: 15/923,781

(22) Filed: Mar. 16, 2018

(51) Int. Cl. H01L 21/67; B01F 3/02; B01F 5/04; G05D 16/20

(52) U.S. Cl. CPC H01L 21/67017; B01F 3/026; B01F 2215/0096; G05D 16/2013; B01F 5/0413

(57) ABSTRACT

Methods of performing high velocity cycle purging in gas specialty systems and the resulting device are provided. Embodiments include providing a gas flow through a vacuum generator connected to a venting reservoir associated with a gas subsystem; detecting a predetermined vacuum level within the venting reservoir; venting the gas with a high velocity through a vent valve connected to the venting reservoir; upon reestablishing the predetermined vacuum level, terminating the venting of the gas; and introducing a dilution purge gas through a purge source valve to pressurize the gas subsystem.

### TECHNICAL FIELD

The present disclosure generally relates to semiconductor manufacturing equipment. In particular, the present disclosure relates to gas delivery equipment used in semiconductor manufacturing.

### BACKGROUND

Many specialty gasses used in semiconductor manufacturing are extremely corrosive. The residual specialty gasses present within connecting hardware of gas delivery systems is very difficult to free, resulting in chronic corrosion, hardware failures, tool downtime, gas leaks and potential product contamination. Corrosion of connecting hardware can occur after only several uses.

The current industry method of preparing gas delivery hardware for container or component replacement is cycle dilution purging based on the mixing of process and purge gases. However, due to restrictive laminar flow rates inherent to vacuum generator devices, such as venturi vacuum generators, there is very low gas velocity and therefore poor mixing.

A need therefore exists for methodology enabling an increase of gas velocity and mixing in vacuum vented systems to prevent corrosion and the resulting device.

### SUMMARY

An aspect of the present disclosure is to improve gas velocity and mixing in vacuum vented systems. Another aspect of the present disclosure is to reduce corrosion in specialty gas systems by increasing gas velocity and mixing in vacuum venturi vented systems.

Another aspect of the present disclosure is to increase gas velocity and mixing in vacuum venturi vented systems by providing a high velocity venting reservoir.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including: providing a gas flow through a vacuum generator connected to a venting reservoir associated with a gas subsystem; detecting a predetermined vacuum level within the venting reservoir; venting the gas with a high velocity through a vent valve connected to the venting reservoir; upon reestablishing the predetermined vacuum level, terminating the venting of the gas; and introducing a dilution purge gas through a purge source valve to pressurize the gas subsystem.

Aspects of the present disclosure include providing the gas flow through a venturi vacuum generator by way of a valve. Other aspects include venting the gas in the gas subsystem with a vacuum reservoir of 120 to 200 cubic centimeters (cc). Another aspect includes repeatedly introducing and restricting the dilution purge gas to pressurize the gas subsystem. Further aspects include venting the gas in the gas subsystem with high velocity and low back pressure at vent valve. Another aspect includes introducing the dilution purge gas through the purge source valve, wherein the dilution purge gas includes an inert gas. Yet another aspect includes the inert gas being nitrogen, argon or helium, or mixtures thereof. Other aspects include providing the gas flow through the vacuum generator, wherein the gas includes an inert gas. Further aspects include the dilution purge gas and residual processing gas being mixed and vented at high velocity and low impedance.

Another aspect of the present disclosure is a device including: a venting reservoir configured to generate high velocity for a gas mixture; a venting valve connected between the venting reservoir and a gas subsystem; and a vacuum source for the venting reservoir, the vacuum source comprising a vacuum generator.

Aspects of the present disclosure include the apparatus being configured for dilution purging of residual processing gas present in connecting hardware of the gas subsystem. Other aspects include the vacuum generator including a venturi vacuum generator. Another aspect includes the venting reservoir providing an evacuated volume of 120 to 200 cc. Further aspects include the gas mixture including a mixture of residual processing gas and inert gas. Another aspect includes the residual processing gas being a corrosive, poisonous, flammable, reactive, or pyrophoric gas, and the inert gas includes nitrogen, argon, helium or mixtures thereof.

A further aspect of the present disclosure is a method including: terminating a flow of a processing gas from a gas container source associated with a gas subsystem; initiating a vacuum generator to achieve a predetermined vacuum level in a high velocity vacuum reservoir connected to the gas subsystem; venting the gas in the gas subsystem with a high velocity through a vent valve connected to the venting reservoir; upon reestablishing the predetermined vacuum level, terminating the venting of the gas; introducing a dilution purge gas through a purge source valve to pressurize the gas subsystem; and purging a gas mixture from the subsystem.

Aspects of the present disclosure include purging the gas mixture by dilution cycle purging. Other aspects include terminating the flow of the processing gas from the gas container source, wherein the processing gas includes a corrosive, poisonous, flammable, reactive, or pyrophoric gas. Another aspect includes venting the gas with high velocity via the venting reservoir evacuated volume of 120 to 200 cc. Further aspects include wherein the venting including turbulent venting.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1 schematically illustrates, a gas specialty subsystem with high velocity cycle purging capability, in accordance with an exemplary embodiment; and

FIG. 2 schematically illustrates, a process flow diagram for dilution cycle purging of a gas specialty system, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of hardware corrosion in specialty gas systems. The problem is solved, inter alia, by venting a gas from a subsystem of with high velocity by way of a high velocity venting reservoir. Existing venturi vacuum generators create a vacuum using a venturi chamber designed to move gases out of a region of space. Venturi vacuum generators rely on the flow of compressed air or gas as the motive fluid to pull or create a vacuum at a desired port. Venturi vacuum generators provide a suitable vacuum, yet are unable to accept a large quantity of gas quickly. The low initial acceleration provides a laminar flow and poor inertial forces to remove the process gas. The method and apparatus of the present disclosure provides magnitudes greater gas acceleration and velocity by eliminating the back pressure problem associated with conventional gas delivery systems. Improved efficacy of venting dramatically reduces corrosion, amount of purge cycles required and dwell times (e.g., labor and materials).

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

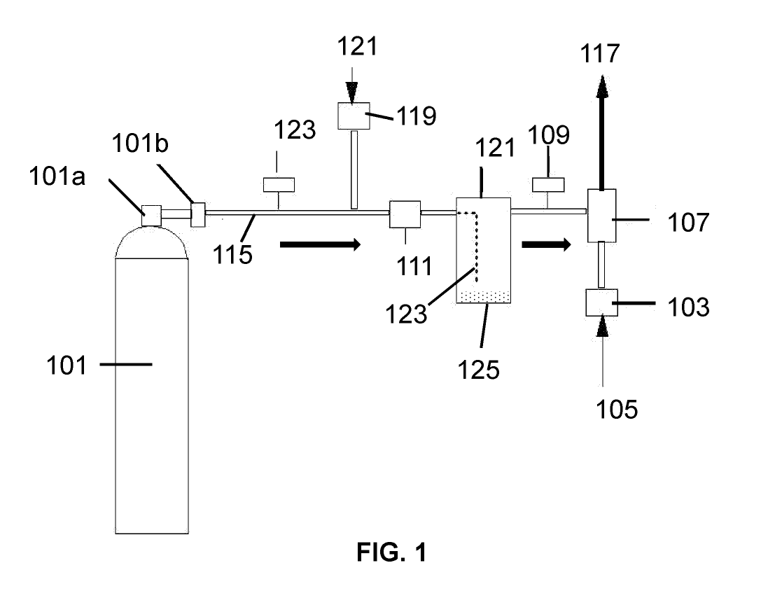

FIG. 1 illustrates a gas specialty subsystem with high velocity cycle purging capability. This gas specialty delivery subsystem is connected to a main gas system and chamber (not shown for illustrative convenience). The specialty gas delivery subsystem of FIG. 1 includes a compressed container 101. The compressed gas container 101 can include a gas cylinder. The compressed gas container 101 can include a pressurized processing/specialty gas such as, but not limited to, hydrogen chloride, hydrogen bromide, chlorine, tungsten hexafluoride or other known semiconductor processing gases. These processing gases are corrosive, poisonous, flammable, reactive, and or pyrophoric in nature. When residual amounts of these processing gases remain in the connecting hardware of a gas delivery subsystem, corrosion and degradation occurs only after a few operational uses of the subsystem. A cylinder valve 101a is positioned on top of the cylinder or container 101 and can be a manual shut off valve or a pneumatically controlled cylinder valve 101a. A valve outlet and connecting fitting 101b correspond to cylinder mating hardware. This hardware can include a Compressed Gas Association (CGA) fitting. The size and thread specifications of the cylinder mating hardware prevent interconnecting gases that are incompatible from coming into contact with each other.

The specialty gas delivery subsystem further includes tubing, a purge valve, a vent valve, pressure transducers, and a venturi generated source of vacuum. Once the compressed gas container 101 is depleted of a processing gas and ready for removal and replacement, a high velocity venting process, in accordance with the present disclosure, is performed to remove the residual processing gas that remains in the subsystem and its connecting hardware. A valve 103 is opened to provide an inert gas 105, such as but not limited to nitrogen, through the venturi vacuum generator 105. After a suitable, predetermined vacuum level is detected at transducer 109, venting valve 111 is opened. The transducer 109 is configured used to convert a certain value of pressure into its corresponding mechanical or electrical output. In certain examples, the vacuum pressure level is 30 inches mercury (Hg). The gas in the connecting hardware 115 is evacuated as an effluent 117 by way of the venturi vacuum generator 107. The mixing that is achieved with the present disclosure is a key aspect to the dilution cycle purging.

Once the vacuum level is reestablished, venting valve 111 is closed and a purge source valve 119 is open. The connecting hardware 115 which includes the cylinder outlet fitting, the metal tubing connected to the cylinder outlet fitting, and the adjacent valves and transducers is pressurized with a purge gas 121 to a predetermined level that is acceptable to cylinder pressure transducer 123, which is in the range of 80-120 pounds per square inch gauge (psig). The purge gas 121 can be an inert gas and selected from nitrogen, argon, helium or mixtures thereof. At this point of the process, or purge cycle, is repeated numerous times such as 30 to 50 times to ensure any residual processing gas is removed from the subsystem.

The result of the process of dilution pulse purging is defined by the following equation:

process gas residual=(pg/pg+pn)ⁿ

wherein pg is the starting process gas pressure (in vent state), pn is the purge pressure being introduced and n is the number of cycles. The process and related apparatus of the present disclosure achieves thorough mixing of the purge and process gases. With conventional methods a problem occurs wherein during the vent portion of the cycle, the gas leaving the connecting hardware overwhelms the volume capacity of the vacuum venturi creating back pressure. The back pressure inhibits the gas from accelerating or reaching a high flow rate. Low laminar flow rates of conventional methods have poor mixing properties, as opposed to high turbulent flow rates of the present disclosure that achieve excellent mixing.

The high speed venting that is achieved with the present method provides a flow force and turbulent condition opposed to the slow laminar flow created by the vacuum venturi back pressure of conventional methods. Turbulent venting of the present disclosure is superior to conventional laminar flow for mixing. The magnitude of the improvement in turbulence can be illustrated by considering the Reynold equation for flow in a pipe. A low Reynold's number indicates poor mixing of gases and a high Reynolds number indicates excellent mixing of gases. The Reynold equation is:

R=QDH/VA

wherein DH is the hydraulic diameter (measured in meters (m)) of the pipe. The hydraulic diameter can be the inside diameter of the pipe if it is circular. Q is the volumetric flow rate (m³/second (s)). A is the pipe's cross-sectional area (m²). V is the kinetic velocity of the fluid (m/s). The present disclosure provides a method and apparatus that significantly increases the volumetric flow rate Q compared to conventional methods that have relatively low initial flow rate Q rates due to back pressure. The present disclosure provides a very high initial flow rate Q resulting in a very high Reynold's number R.

A further advantage of the present disclosure is the physical configuration of the tube 123 within the vacuum venting reservoir 121. At the point where the vented process gas expands there will be a Joules Thompson effect for cooling the vented gas. Given many processing gases are liquefied, and heavier than the purge gas, some condensation 125 will occur. The outlet of tube 123 at the bottom of the vacuum venting reservoir 121 provides a trap for any molecules of the processing gases that have condensed and the trap discourages back diffusion. The vacuum venting reservoir 121 provides an evacuated volume of 120 to 200 cc.

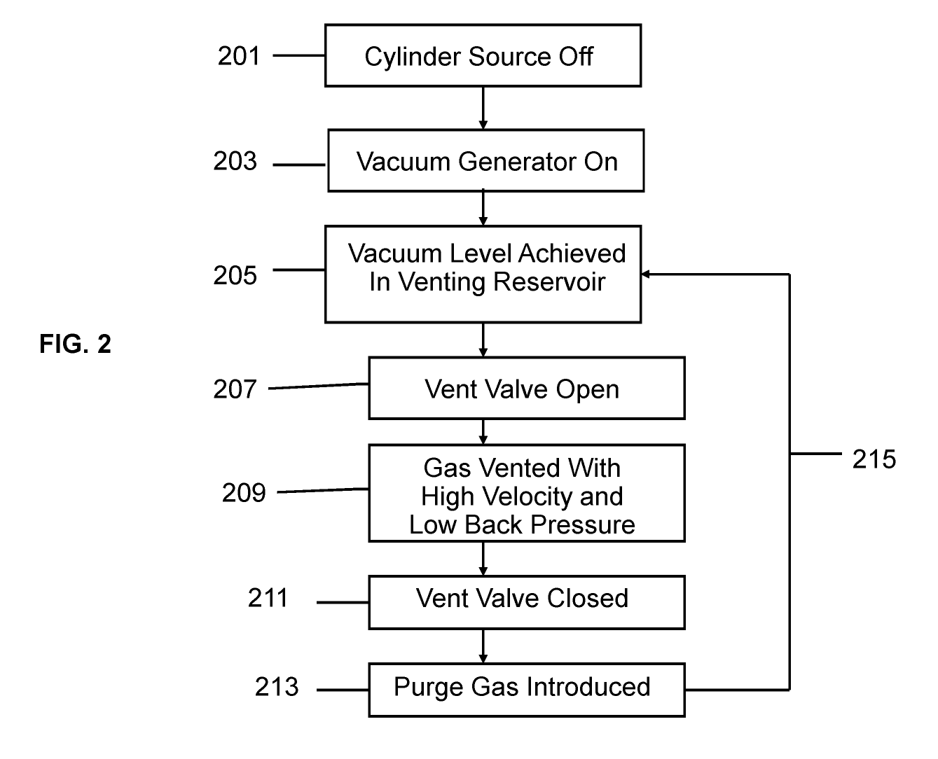

FIG. 2 depicts a process flow diagram for dilution cycle purging of a gas specialty system, in accordance with an exemplary embodiment. The method includes terminating the flow of a process or specialty gas from the compressed gas container or cylinder (Step 201) by closing a valve associated with the container or cylinder, the valve may be a manual cylinder valve or pneumatically controlled cylinder valve. Once the compressed gas container or cylinder is depleted of a processing gas and ready for removal and replacement, a high velocity venting process, in accordance with the present disclosure, is performed to remove the residual processing gas that remains in the subsystem and its connecting hardware. A venturi vacuum generator is started (Step 203) and an inert gas is provided to achieve a suitable vacuum level in the venting reservoir is detected by way of a vacuum pressure transducer (Step 205). A venting valve is opened (Step 207) by way of automated (e.g., pneumatic) control to vent the gas in the gas subsystem with a high velocity to the venting reservoir (Step 209). Upon reestablishing as predetermined vacuum level, the venting of the gas is terminated by closing the vent valve (Step 211) by way of automated (e.g., pneumatic) control. A dilution purge gas is introduced (Step 203) through a purge source valve to pressurize the gas subsystem. The process is repeated (Step 215) to purge a mixture of the processing gas and purge gas from the subsystem.

An aspect of the method according to FIG. 2 is to provide a process for overcoming the flow limitations in venturi vacuum generators that create back pressure and limit the velocity and mixing during venting. Similar to using capacitance to mitigate voltage spikes, the high velocity venting reservoir accepts the gas mixture being vented with high velocity and low impedance. Initial flow velocity is reciprocal to the initial back pressure. Measurement of the back pressure of the apparatus of the present disclosure was performed, and a very low back pressure was detected during the first 10 milliseconds (ms) which demonstrated a high velocity gas flow. During the first 10 ms, the apparatus of the present disclosure using the high velocity venting reservoir reduced the back pressure 20 times more than a conventional venturi vacuum generator. Peak back pressure is 80% lower than with a conventional a venturi vacuum generator. Back pressure was measured by a pressure transmitting gauge at a point between the vent valve 111 and the vacuum reservoir 121 (FIG. 1).

The embodiments of the present disclosure can achieve several technical effects including enabling the venting of caustic, corrosive specialty gases from specialty gas systems at a high velocity by way of a high velocity cycle purging. Embodiments of the present disclosure can also enjoy utility in various industrial applications as, for example, semiconductor fabrication plants that produce components used in microprocessors, smart phones, mobile phones, cellular handsets, set-top boxes, DVD recorders and players, automotive navigation, printers and peripherals, networking and telecom equipment, gaming systems, and digital cameras. The present disclosure enjoys industrial applicability in any of various types specialty gas systems used in semiconductor manufacturing.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure can use various other combinations and embodiments and is capable of any changes or modifications within the scope of the inventive concept as expressed herein.

What is claimed is:

1. A method comprising:
providing a gas flow through a vacuum generator connected to a venting reservoir associated with a gas subsystem;
detecting a predetermined vacuum level within the venting reservoir;
venting the gas with a high velocity through a vent valve connected to the venting reservoir;
upon reestablishing the predetermined vacuum level, terminating the venting of the gas; and
introducing a dilution purge gas through a purge source valve to pressurize the gas subsystem.

2. The method according to claim 1, comprising:
providing the gas flow through a venturi vacuum generator by way of a valve.

3. The method according to claim 1, comprising:
venting the gas in the gas subsystem with a vacuum reservoir of 120 to 200 cubic centimeters (cc).

4. The method according to claim 1, comprising:
repeatedly introducing and restricting the dilution purge gas to pressurize the gas subsystem.

5. The method according to claim 1, comprising:
venting the gas in the gas subsystem with high velocity and low back pressure at vent valve.

6. The method according to claim 5, comprising:
introducing the dilution purge gas through the purge source valve, wherein the dilution purge gas comprises an inert gas.

7. The method according to claim 6, wherein the inert gas comprises nitrogen, argon or helium, or a mixture thereof.

8. The method according to claim 1, comprising:
providing the gas flow through the vacuum generator, wherein the gas comprises an inert gas.

9. The method according to claim 8, wherein the dilution purge gas and residual processing gas are mixed and vented at high velocity and low impedance.

10. An apparatus comprising:
a venting reservoir configured generate high velocity for a gas mixture;
a venting valve connected between the venting reservoir and a gas subsystem; and
a vacuum source for the venting reservoir, the vacuum source comprising a vacuum generator.

11. The device according to claim 10, wherein the apparatus is configured for dilution purging of residual processing gas present in connecting hardware of the gas subsystem.

12. The device according to claim 11, wherein the vacuum generator comprises a venturi vacuum generator.

13. The device according to claim 12, wherein venting reservoir provides an evacuated volume of 120 to 200 cubic centimeter (cc).

14. The device according to claim 11, wherein the gas mixture comprises a mixture of residual processing gas and inert gas.

15. The device according to claim 14, wherein:
the residual processing gas comprises a corrosive, poisonous, flammable, reactive, or pyrophoric gases, and
the inert gas comprises nitrogen, argon, helium or a mixture thereof.

16. A method comprising:
terminating a flow of a processing gas from a gas container source associated with a gas subsystem;
initiating a vacuum generator to achieve a predetermined vacuum level in a high velocity vacuum reservoir connected to the gas subsystem;
venting the gas in the gas subsystem with a high velocity through a vent valve connected to the venting reservoir;
upon reestablishing the predetermined vacuum level, terminating the venting of the gas;
introducing a dilution purge gas through a purge source valve to pressurize the gas subsystem; and
purging a gas mixture from the subsystem.

17. The method according to claim 16, further comprising:
purging the gas mixture by dilution cycle purging.

18. The method according to claim 16, comprising:
terminating the flow of the processing gas from the gas container source, wherein the processing gas comprises a corrosive, poisonous, flammable, reactive, or pyrophoric gas.

19. The method of claim 16, comprising:
venting the gas with high velocity via the venting reservoir evacuated volume of 120 to 200 cubic centimeter (cc).

20. The method of claim 19, wherein the venting comprises turbulent venting.
